(19) United States
(12) Patent Application Publication
(10) Pub. No.: US 2013/0266739 A1
(43) Pub. Date: Oct. 10, 2013

(54) PROCESS FOR FORMING CARBON FILM OR INORGANIC MATERIAL FILM ON SUBSTRATE BY PHYSICAL VAPOR DEPOSITION

(71) Applicants: Shih-Yen LIN, Taipei (TW); Meng-Yu Lin, Taipei (TW); Shu-Han Chen, Taipei (TW)

(72) Inventors: Shih-Yen LIN, Taipei (TW); Meng-Yu Lin, Taipei (TW); Shu-Han Chen, Taipei (TW)

(73) Assignee: ACADEMIA SINICA, Taipei (TW)

(21) Appl. No.: 13/591,815

(22) Filed: Aug. 22, 2012

(30) Foreign Application Priority Data
Apr. 6, 2012 (TW) 101112382

(51) Int. Cl. C23C 16/26; C23C 14/34; C23C 16/02; B82Y 40/00

(52) U.S. Cl. 427/535; 427/249.1; 427/577; 977/844

(57) ABSTRACT

The present invention discloses a process for forming a carbon film or an inorganic material film on a substrate by physical vapor deposition (PVD). Through the process, a high-quality, wafer scale thin film, such as a graphene film, is directly formed on a substrate without using an additional transfer step.

### FIELD OF THE INVENTION

The present invention relates to a process for forming a carbon film or an inorganic material film on a substrate by physical vapor deposition (PVD), and more particularly to a process for directly forming a high-quality, wafer-scale graphene film on a substrate by radio frequency sputtering.

### DESCRIPTION OF THE RELATED ART

Graphene, which is essentially a one-atom thick layer of graphite, has been the subject of particular interest due to its two-dimensional structure and unique physical properties, for example, carrier mobility of up to 200,000 cm²/V·s, as well as excellent mechanical strength and heat transfer properties, allowing it to satisfy performance requirements imposed by high-speed, high-performance electronic devices.

Various processes for synthesizing graphene have been developed to date, for example, (1) exfoliation from highly ordered pyrolytic graphite (HOPG); (2) SiC sublimation; and (3) chemical vapor deposition (CVD), which is performed on a catalytic metal (for example, copper, nickel, and iron).

Although high-quality monolayer graphene can be obtained by exfoliation of highly ordered pyrolytic graphite or mechanical exfoliation of graphite, these processes cannot produce thin sheets of substantial area. Si sublimation performed on a SiC substrate can provide a large-area graphene thin sheet of a controllable number of graphene layers; however, the SiC substrate is costly. Therefore, the limitations of these methods severely restrict their value in practical application.

Recent research has found that use of CVD on a catalytic metal substrate, such as nickel (Ni) and copper (Cu), can form graphene film that is both high quality and large in area. This technology may be used in a transparent electrode of a high-penetrating and flexible substrate; see, for example, Reina, A. et. al., Nano Letters 2008, 9, 30-35; Li, X. et. al., Science 2009, 324, 1312-1314; and Sukang, B., et. al., Nature Nanotechnology, 2010, 5, 574-578. Graphene has been previously reported in literature to be formed on a copper substrate by CVD (ACS Nano 2011, 5, 3385-3390), with benzene as a carbon source precursor, at an operating temperature that is emphasized to be as low as 300° C. However, this method employs pre-treatment temperature of up to 1000° C.

In addition, in the prior art (Byun, S. J. et. al., The Journal of Physical Chemistry Letters 2011, 2, 493-497), graphene has been synthesized with a nickel metal substrate by CVD; however, solid dissolution of carbon source molecules and nickel metal occurs at high temperature, and when the temperature drops, the carbon atoms evolve from the surface of nickel metal and are rearranged into the structure of graphene. Therefore, the method cannot ensure accurate control of the amount of carbon atoms evolved, making it difficult to control the number of graphene films produced.

The current formation technology still requires an additional transfer process, to transfer the graphene film originally formed on the metal substrate to a desired substrate. For example, a commonly used technique is grasping the graphene film formed on the copper substrate by using a polymer support layer (for example, PMMA), then etching the copper substrate, and transferring the graphene film to a desired substrate and dissolving the polymer support layer, thereby leaving the graphene film on the desired substrate. In the transfer process, it is easy for the graphene film to become ruptured and irregularly folded, and for polymer residues to remain on the surface of the graphene film, thus compromising the excellent material properties of the graphene film. Moreover, the transfer process is incompatible with current semiconductor process technology (for example, silicon processing), thereby limiting the prospect of wafer-scale production of integrated circuit elements.

A process for directly forming graphene on a substrate is also reported in literature. In the process, a carbon-based polymer or an amorphous carbon film is used as a solid carbon source, on which a nickel metal layer is deposited. The solid carbon source is catalytically converted into a graphene structure in the presence of nickel metal at a high temperature (about 800° C. to about 1100° C.). After removing the nickel metal layer, graphene directly formed on a substrate is obtained. However, it is difficult to control the nickel metal so as to obtain a thin film graphene, and well graphitized, high-quality graphene cannot be formed if the catalytic conversion temperature is lower than 800° C.

Therefore, there is still a need for developing a process for large-scale, low-cost manufacturing of a semiconductor substrate for practical applications, and especially a process for directly forming a wafer-scale, high-quality graphene film on a substrate.

### BRIEF SUMMARY OF THE INVENTION

The present invention is directed to a process for forming a carbon film or an inorganic material film on a substrate, through which a wafer-scale, high quality thin film, such as a graphene film, can be directly formed on a substrate without using an additional transfer step.

### BRIEF DESCRIPTION OF THE DRAWINGS

FIG. 1(a) shows photos of a carbon film sample above and below a Ni film after being subjected to an annealing temperature of 1100° C.;

FIG. 1(b) shows 30×30 μm² atomic force microscope images of a carbon film sample above and below a Ni film after being subjected to an annealing temperature of 1100° C.;

FIG. 2 is a Raman spectrum of a sample below a Ni film after being subjected to an annealing temperature of 800° C., 1000° C., and 1100° C.;

FIG. 3 is a Raman spectrum of a sample after being subjected to a single and double Ni deposition/1100° C. annealing/Ni removal step;

FIG. 4(a) shows a fabrication procedure of selective carbon film deposition; and

FIG. 4(b) shows optical micrographs of a sample before and after removal of a Ni film.

### DETAILED DESCRIPTION OF THE INVENTION

In the specification and claims, the singular forms “a,” “an,” and “the” include the plural unless the context clearly dictates otherwise. The use of any and all examples or exemplary language (e.g., “such as”) provided herein is intended merely to better illuminate the invention and does not pose a limitation on the scope of the invention unless otherwise claimed. No language in the specification should be construed as indicating any non-claimed element as essential to the practice of the invention.

The present invention provides a process for directly forming a carbon film or an inorganic material film on a substrate, including:
(a) forming a metal film on a substrate, to obtain a catalytic substrate;
(b) forming a carbon film or an inorganic material film with carbon atoms or inorganic material atoms on one or two surfaces of the catalytic substrate by using a PVD system; and
(c) removing the metal film on the substrate.

In the process according to the present invention, the “substrate” may be any substrate known in the art, including, but not limited to, a silica substrate, a quartz substrate, a sapphire substrate, a boron nitride substrate, a glass substrate, a metal substrate, or a semiconductor substrate.

In the process according to the present invention, the “metal film” may be formed of any metal known in the art, including, but not limited to, copper, iron, cobalt, nickel, gold, silver, or a mixture thereof. Preferably, the metal film is formed of nickel.

In the process according to the present invention, the thickness of the metal film is not particularly limited, typically in the range of about 10 nm to about 1 μm, and preferably about 100 nm to about 300 nm.

In the process according to the present invention, the “catalytic substrate” refers to a substrate on which a catalytic metal film is formed.

In the process according to the present invention, the step of forming the carbon film or the inorganic material film on one or two surfaces of the catalytic substrate is carried out by using a PVD system. Generally, typical PVD may include evaporation, molecular beam epitaxy, and sputtering. Sputtering is widely used in the semiconductor industry, since the ingredients of the sputtered atoms and the deposition thickness can be accurately controlled.

A sputtering system generally includes a direct current (DC) sputtering system and a radio frequency sputtering system. The DC sputtering system is merely applicable to a conductive target, and the radio frequency sputtering system is applicable to a conductor and an insulator, as well as insulators having a low evaporation pressure such as SiO₂, Al₂O₃, Si₃N₄, and glass. In a preferred embodiment of the present invention, a radio frequency sputtering system is used to form a carbon film or an inorganic material film on one or two surfaces of the catalytic substrate.

In the sputtering system, a typical operation plasma power is in the range of about 0 W to about 300 W, and a suitable range of the operation plasma power depends on a selected carbon atom source or inorganic material atom source. For example, the plasma power range required by nickel atoms is about 20 W or higher, and the plasma power range required by graphite carbon atoms is about 75 W or higher.

In the process according to the present invention, the carbon atom source is amorphous carbon, which may be doped with other ingredients, for example, hydrogen, nitrogen, boron or a mixture thereof.

In the process according to the present invention, the inorganic material source may be any inorganic material source known in the art, including, but not limited to, boron nitride, molybdenum disulfide, zinc sulfide, zinc telluride, zinc selenide, bismuth selenide, bismuth telluride or a mixture thereof.

In the present invention, one or more carbon films or inorganic material films may be formed by Step (b). In a preferred embodiment of the present invention, the carbon film is a graphene film.

In the process according to the present invention, the carbon film or the inorganic material film may be directly patterned on a variety of substrates. For example, the nickel film may be patterned on the substrate by lithography (including, but not limited to, photolithography, soft lithography, electron-beam lithography, nanoimprint lithography, dip-pen nanolithography or other patterning technology), so that a desired film (for example, a graphene film) may be directly formed on a bottom layer of the patterned metal film. Therefore, the patterned carbon film or inorganic material film may be directly obtained on a variety of substrates.

The Step (c) of removing the metal film on the substrate may be carried out by any technology known in the art, including, but not limited to, (1) etching with an etching solution, (2) electrochemical etching, (3) mechanical removal, and (4) other physical removal. The “etching solution” includes any chemical known in the art that can etch the metal without damaging the carbon film or the inorganic material film or leaving residue. In an embodiment of the present invention, the nickel film is etched with an aqueous HCl solution. The “other physical removal” includes, is but not limited to, polishing or removal with an adhesive tape.

A stack structure may also be obtained by the process according to the present invention. For example, through PVD, the carbon film or the inorganic material film can be formed on the top layer and the bottom layer of the metal film. In the removal step, if only the carbon film or the inorganic material film on the top layer is removed, a monolayer carbon film or inorganic material film on the substrate can be obtained; if the carbon film or the inorganic material film on the top layer is not removed, after the metal film is etched, the carbon film or the inorganic material film on the top layer is stacked on that on the bottom layer to form a stack structure. In addition, if the metal film is partially etched or etched to have a specific structure (for example, dot-like, rod-like, or annular nanostructure), a sandwich stack structure of carbon film or inorganic material film/nanostructure/carbon film or inorganic material film is formed.

In a preferred embodiment of the present invention, a pre-treatment step is conducted before the step of forming the carbon film or the inorganic material film on the catalytic substrate, in which the substrate may be reduced, for example, in a hydrogen-containing atmosphere (for example, hydrogen or ammonia), and oxygen atoms on the surface of the substrate are removed. Meanwhile, the dimension of the metal grain may also be controlled by pre-treatment, thereby providing a surface that is planar and suitable for forming the carbon film or the inorganic material film. The pre-treatment step may be conducted by any technology known in the art, including, but not limited to, thermal annealing or hydrogen plasma. During thermal annealing, a typical temperature range is from about 500° C. to about 1100° C., and preferably from about 700° C. to about 1000° C.

In a preferred embodiment of the present invention, the annealing step is conducted after the step of forming the carbon film or the inorganic material film on the catalytic substrate. During the annealing step, a typical temperature range is generally from about 600° C. to about 1200° C., and preferably from about 800° C. to about 1100° C.

In the process according to the present invention, the carbon film or the inorganic material film formed on the surface of the catalytic substrate may be removed by a conventional technology in the art after the step of forming the carbon film or the inorganic material film on the catalytic substrate. In a preferred embodiment of the present invention, the graphite thin film formed on the surface of the catalytic substrate is removed with oxygen plasma.

In the process of the present invention, after the annealing step and Step (c), a combination of Step (a), the annealing step, and Step (c) may be repeated one or more times, to form a better carbon film or inorganic material film on the substrate based on the previously formed carbon film or inorganic material film, so as to decrease the sheet resistance. In a preferred embodiment of the present invention, after the annealing step and Step (c), a combination of Step (a), the annealing step and Step (c) may be additionally implemented, to further form a graphene film having a low sheet resistance on the substrate based on the previously formed graphene film.

In the preferred embodiment of the present invention, a nickel film is used, and the carbon atoms are allowed to form a graphene film on the catalytic substrate by PVD. The carbon atoms diffuse from the grain boundary to an interface between the surface of nickel and the underlying substrate. Because carbon atoms diffuse and evolve from the grain boundary merely, the number of graphene layers can be precisely controlled (that is, to form monolayer, dual-layer, or tri-layer graphene film). Moreover, the process can directly form a continuous and uniform high quality graphene film of large area on the substrate without using any additional transfer step. The formed graphene film exhibits excellent properties such as high conductivity and high light transmittance.

The process according to the present invention is based on a formation mechanism of evolution from the bottom, and thus a patterning process may be performed first on the nickel film, and a patterned graphene film can be obtained on the bottom layer after the nickel film is formed and removed. Therefore, the process according to the present invention can be integrated into the existing semiconductor process, to fabricate a graphene integrated circuit element.

Because the process according to the present invention is also applicable to a low-melting material (for example, a glass substrate), a graphene film can be directly formed at a low temperature (for example, about 500° C.), thereby lowering the cost of thermal processing.

The process according to the present invention may be useful for many applications, including, but not limited to, integrated circuit elements (for example, memory, logic circuits, and radio frequency circuits), transparent conductive films (such as film transistor displays, touch panels, solar cells, and light emitting diodes), super capacitors and functional composite materials (such as a sandwich structure of graphene/metal or metal ion/graphene), and sensing components (such as biomedical, gas, chemical, temperature or stress sensors).

In a specific embodiment of the present invention, the graphene carbon film is prepared by forming an amorphous carbon film on a SiO₂/Si substrate covered with a 100 nm Ni film by a radio frequency sputtering system, and then performing a high-temperature annealing step. A large-area graphite carbon film can be obtained above and below the Ni film after a standard film transfer procedure and direct etching of the Ni film. The results of the embodiment show that graphite carbon deposition occurs between the interfaces of vacuum/Ni and Ni/SiO₂. It can be known from the increase of the intensity of the sharp G peak and 2D peak that using a high temperature of 800° C. to 1100° C. can provide good film crystallization quality. Therefore, by using the process of the present invention, a film with good conductivity can be prepared at a high annealing temperature. The process of the present invention can deposit the conductive graphene film on an insulator with orientation selectivity, or can be used in conventional semiconductor manufacturing technology.

Details of one or more embodiments of the present invention are depicted in accompanying drawings and description below. Other features, objectives, and advantages of the present invention may be easily understood according to the description, drawings, and claims.

### EXAMPLES

The following specific example should be construed as illustration instead of limitation in any way of the rest of the present invention. Those skilled in the art can utilize the present invention to the fullest extent according to the description herein without further depiction.

A graphite carbon film was obtained by using a radio frequency sputtering system, with 300 nm SiO₂/Si and quartz as a substrate, following the steps below: (a) deposition of an amorphous carbon film at a plasma power of 90 W for 11 minutes; (b) deposition of 100 nm Ni at a plasma power of 40 W; and (c) annealing at a high temperature for 15 minutes. After the annealing step, the sample was taken from a chamber, and the following Ni removal steps were performed: (a) 20-min oxygen plasma treatment to remove the graphite film on the surface, and (b) immersion in 10% aqueous HCl solution, to remove the Ni film.

The sheet resistance of the sample formed on the SiO₂/Si substrate was measured by a four-point probe; the transmittance of the film formed on the quartz substrate was measured by a Dynamica Halo RB-10 spectrometer; and Raman spectrum of the sample formed on the SiO₂/Si substrate was measured by an NT-MDT NTEGRA spectrometer system.

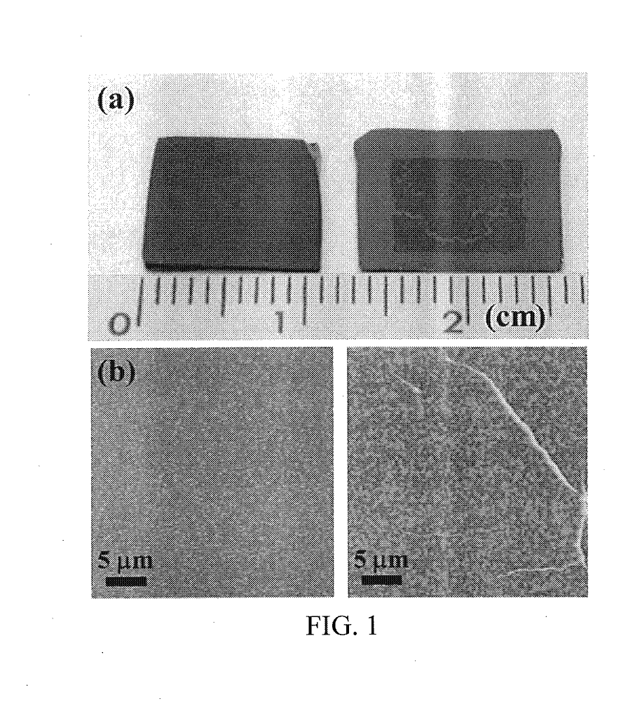

FIG. 1(a) is a photo of a carbon film sample above and below a Ni film after being subjected to an annealing temperature of 1100° C. The carbon film above the Ni film was attached to another 300 nm SiO₂/Si substrate after a standard film transfer step. As shown in FIG. 1(a), after the film transfer step, the film is non-continuous; however, the carbon film covering the whole substrate below the Ni film is a complete carbon film. This shows one of the defects of graphene prepared by CVD; that is, the film is easily damaged in the film transfer step.

Regarding the surface morphology, FIG. 1(b) shows 30×30 μm² atomic force microscope images of the two samples. As shown in FIG. 1(b), the carbon film below the Ni film is not folded. Therefore, even if the film after the film transfer step has no visible film damage, folds visible under a microscope may exist. It can be seen from the carbon film above and below the Ni film that C deposition occurs between the interfaces of vacuum/Ni and Ni/SiO₂.

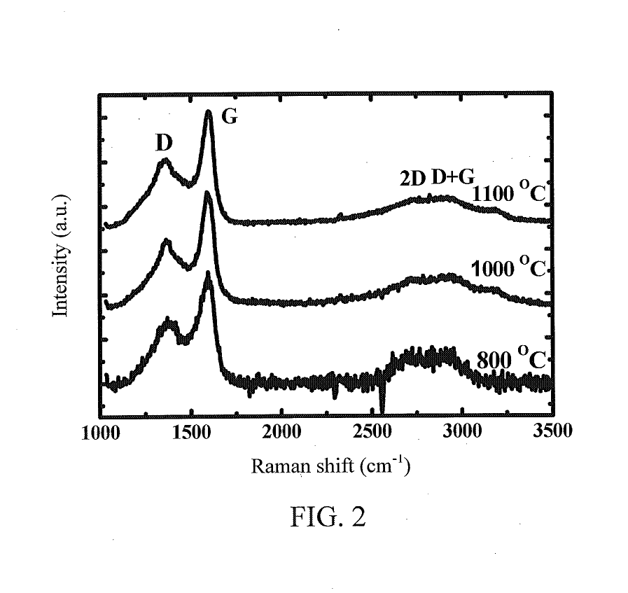

FIG. 2 is a Raman spectrum of a sample below the Ni film after being subjected to an annealing temperature of 800° C., 1000° C., and 1100° C. In the Raman spectrum, the three samples show peaks at 1330(D) and 1600 (G)cm⁻¹. As the annealing temperature of the sample is higher, the peak intensity at 2650(2D) and 2920(D+G) cm⁻¹ is higher. It can be known from the high D peak intensity of the three samples that the film obtained by using the process of the present invention is a polymorphous film having multiple grain boundaries, which needs to be further studied because the atom mobility in the annealing process may be insufficient. FIG. 2 also shows another phenomenon: the higher the annealing temperature is, the sharper the G and D peaks are. Therefore, a better crystallization quality may be obtained at a higher temperature.

The sheet resistance of the samples obtained at the annealing temperature of 800° C., 1000° C., and 1100° C. was respectively 4×10⁹, 2.68×10⁵, and 4.33×10⁵ Ω/□. The results show that a better carbon crystallization quality can give rise to better conductivity of the film. The samples obtained at the annealing temperature of 1000° C. and 1100° C. have a high transmittance of 86.9% and 87.3% at 550 nm. Therefore, the process of the present invention is applicable to the fabrication of a transparent electrode.

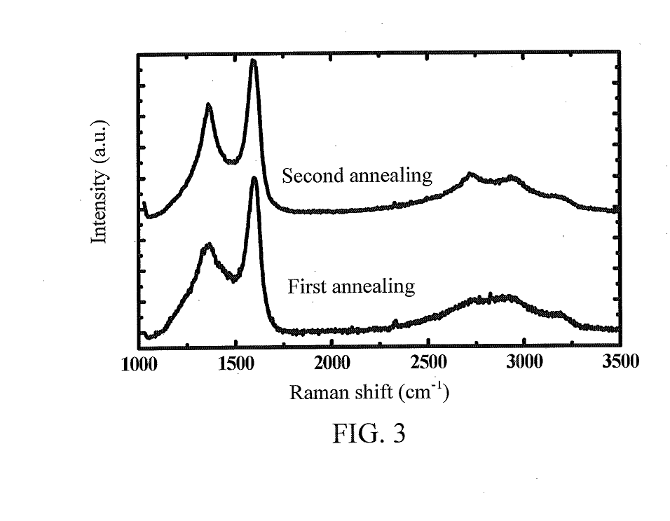

Compared with ITO having a sheet resistance of several Ω/□, the sheet resistance of the carbon film prepared by the process of the present invention is several orders of magnitude higher. In order to overcome this defect, i.e., to reduce the sheet resistance of the carbon film, in the process of the present invention, the annealing step is repeatedly performed to improve the crystallization quality, so as to improve the conductivity of the resulting film. Specifically, after the step of removing the first deposited Ni film, a new Ni film is further deposited on the graphite carbon film, and annealed at a temperature of 1100° C. FIG. 3 is a Raman spectrum of a sample after being subjected to a single and double Ni deposition/1100° C. annealing/Ni removal step. By the additional annealing step, the sheet resistance of the carbon film is decreased from 4.33×10⁵ to 1.36×10⁴ Ω/□. The results show that, in the repetition of the annealing step, C dissolution and precipitation occur for carbon atoms that are not yet sp² bonded. Optimal formation conditions for atom carbon source may be studied in the future.

In addition, because C precipitation only occurs at the position of the Ni film, selective graphene precipitation can be achieved by standard metal precipitation, patterning (photo etching), or a metal exfoliation step. Therefore, in the process of the present invention, selective graphene deposition may be performed on a patterned substrate, to obtain a patterned carbon film below the metal film without using a transfer step.

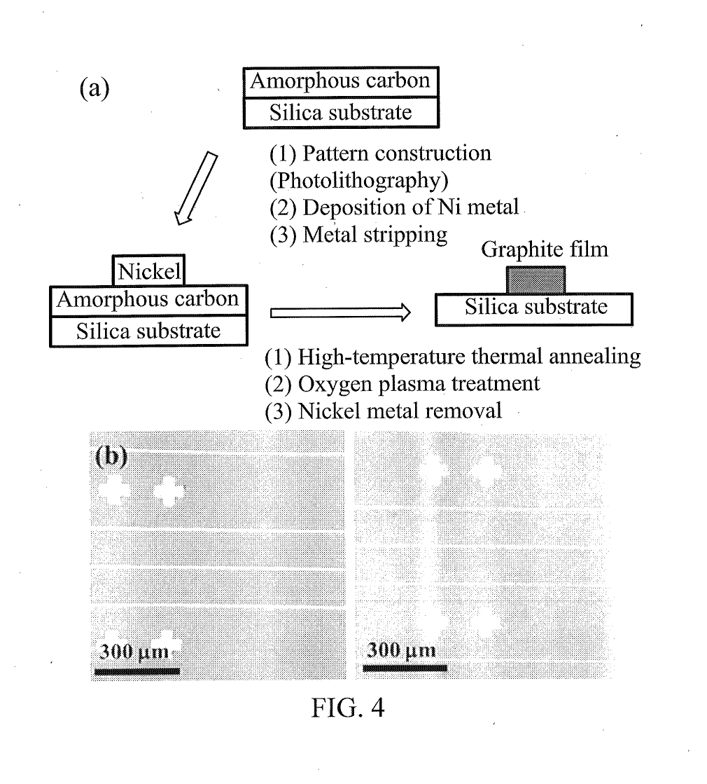

FIG. 4(a) shows a fabrication procedure of selective carbon film deposition. After amorphous carbon deposition occurs by sputtering, a patterned Ni film may be further fabricated by a standard processing procedure, and a patterned graphite carbon film can be obtained after annealing at 1100° C. and oxygen plasma treatment/metal exfoliation step. FIG. 4(b) shows optical micrographs of a sample before and after removal of a Ni film. As shown in FIG. 4(b), the same pattern can be observed on the patterned Ni film and the finally formed carbon film. Therefore, if needed, selective carbon film deposition on a planar or patterned substrate may be achieved by forming a graphite carbon film below the Ni film by the process of the present invention. The present invention also provides a process for selectively depositing graphene on any substrate to improve crystallization quality of the graphene without requiring any additional film transfer step.

All the features disclosed in this specification may be combined at will. Each feature disclosed in this specification may be replaced by alternative features used for the same, equivalent, or similar purposes. Therefore, unless indicated otherwise, each feature disclosed is only an example of a series of equivalent or similar features.

Some embodiments of the present invention have been described. However, it should be understood that various modifications may be made without departing from the spirit and scope of the present invention. Therefore, other embodiments also fall with the scope of the following claims.

We claim:

1. A process for directly forming a carbon film or an inorganic material film on a substrate, comprising:
(a) forming a metal film on a substrate, to obtain a catalytic substrate;
(b) forming a carbon film or an inorganic material film with carbon atoms or inorganic material atoms on one or two surfaces of the catalytic substrate by using a physical vapor deposition (PVD) system; and
(c) removing the metal film on the substrate.

2. The process according to claim 1, wherein the substrate is a silica substrate, a quartz substrate, a sapphire substrate, a boron nitride substrate, a glass substrate, a metal substrate, a semiconductor substrate, or a combination thereof

3. The process according to claim 1, wherein the metal film is formed of copper, iron, cobalt, nickel, gold, silver, or a mixture thereof

4. The process according to claim 3, wherein the metal film is formed of nickel.

5. The process according to claim 1, wherein the thickness of the metal film is in the range of about 10 nm to about 1 μm.

6. The process according to claim 5, wherein the thickness of the metal film is in the range of about 100 nm to about 300 nm.

7. The process according to claim 6, wherein the PVD system is a radio frequency sputtering system.

8. The process according to claim 7, wherein the operation range of the plasma power of the radio frequency sputtering system is from about 0 W to about 300 W.

9. The process according to claim 1, wherein the carbon atom source is amorphous carbon.

10. The process according to claim 1, wherein the carbon atom source is doped with nitrogen, boron or a mixture thereof

11. The process according to claim 1, wherein multiple carbon films or inorganic material films are formed on one or two surfaces of the catalytic substrate.

12. The process according to claim 1, wherein the carbon film is a graphene film.

13. The process according to claim 1, wherein the carbon film or the inorganic material film is patterned.

14. The process according to claim 1, wherein Step (c) is performed through etching with an etching solution, electrochemical etching, mechanical removal, or other physical removal.

15. The process according to claim 14, wherein Step (c) is performed through etching with an etching solution.

16. The process according to claim 15, wherein the etching solution is an aqueous HCl solution.

17. The process according to claim 1, wherein a stack structure is obtained.

18. The process according to claim 1, comprising a pre-treatment step before Step (b).

19. The process according to claim 18, wherein the pre-treatment step is reducing the substrate under a hydrogen-containing atmosphere and removing oxygen atoms on the surface of the substrate.

20. The process according to claim 18, wherein the pre-treatment step is thermal annealing.

21. The process according to claim 18, wherein the pre-treatment step is performed with hydrogen plasma.

22. The process according to claim 1, comprising an annealing step after Step (b).

23. The process according to claim 22, wherein the operation temperature of the annealing step is in the range of about 600° C. to about 1200° C.

24. The process according to claim 22, after Step (b), comprising a step of removing the carbon film or the inorganic material film on the surface of the catalytic substrate with oxygen plasma.

25. The process according to claim 22, after the annealing step and Step (c), further comprising repeating a combination of Step (a), the annealing step, and Step (c) one or more times.
